(19) United States
(12) Patent Application Publication
(10) Pub. No.: US 2012/0068258 A1
(43) Pub. Date: Mar. 22, 2012

(54) SEMICONDUCTOR DEVICE AND METHOD FOR MANUFACTURING SAME

(75) Inventors: Syotaro ONO, Kanagawa-ken (JP); Wataru Saito, Kanagawa-ken (JP); Shunji Taniuchi, Kanagawa-ken (JP); Miho Watanabe, Miyagi-ken (JP); Hiroaki Yamashita, Tokyo (JP)

(73) Assignee: Kabushiki Kaisha Toshiba, Tokyo (JP)

(21) Appl. No.: 13/052,908

(22) Filed: Mar. 21, 2011

(30) Foreign Application Priority Data
Sep. 17, 2010 (JP) 2010-210134

(51) Int. Cl. H01L 29/78; H01L 21/28

(52) U.S. Cl. 257/329; 438/585; 257/E29.262; 257/E21.19

(57) ABSTRACT

According to one embodiment, a semiconductor device includes a first main electrode, a control electrode, an extraction electrode, a second insulating film, a plurality of contact electrodes, and a control terminal. The first main electrode is electrically connected to a first semiconductor region of a first conductivity type and a second semiconductor region of a second conductivity type selectively provided on a surface of the first semiconductor region. The control electrode is provided on the first semiconductor region via a first insulating film. The extraction electrode is electrically connected to the control electrode. The second insulating film is provided on the first main electrode and the extraction electrode. The plurality of contact electrodes are provided in an inside of a plurality of first contact holes formed in the second insulating film and are electrically connected to the extraction electrode. The control terminal covers portions of the first main electrode provided on the first semiconductor region, on the second semiconductor region, and on the control electrode, respectively, and the extraction electrode, is electrically connected to the plurality of contact electrodes, and is electrically insulated from the first main electrode by the second insulating film.

### CROSS-REFERENCE TO RELATED APPLICATIONS

This application is based upon and claims the benefit of priority from the prior Japanese Patent Application No. 2010-210134, filed on Sep. 17, 2010; the entire contents of which are incorporated herein by reference.

### FIELD

Embodiments described herein relate generally to a semiconductor device and a method for manufacturing the same.

### BACKGROUND

A power semiconductor device, such as a MOSFET (Metal Oxide Semiconductor Field Effect Transistor) or an IGBT (Insulated Gate Bipolar Transistor), has high-speed switching properties and a reverse-direction blocking voltage (breakdown voltage) of several dozen to several hundred volts, and thus it is widely used in power conversion and power control for household appliances, communication devices and vehicle motors. In these fields, downsizing, high efficiency and low power consumption of a semiconductor device, are also strongly required.

For example, Ron×S that is a product of the on resistance Ron and the area of a chip S can be considered as a performance index independent of the chip area of a semiconductor device. Even if the chip area S is simply reduced to downsize the semiconductor device, Ron becomes large in inverse proportion to the chip area S, and thereby the value of Ron×S does not decrease. Therefore, in order to achieve downsizing of the semiconductor device on the basis of high efficiency and low power consumption, and thus it is important to make the value of Ron×S small.

In order to make the value of Ron×S small, making Ron per unit area small by optimization or improvement of element structure, and enlarging the rate of the effective area, through which on current flows, occupying on the chip surface, are included. For example, by forming a channel, through which the on current passes, under a gate electrode pad, it is possible to lower Ron and make the value of Ron×S small by making relative effective area large without changing the chip area S.

However, there has been a problem that a source electrode is not directly brought into contact with the channel provided under the gate electrode pad, and thus element destruction may occur due to avalanche breakdown. For this reason, the formation of a channel serving as the passage of the on current under the gate electrode pad has been uncommon. Therefore, a semiconductor device capable of suppressing avalanche breakdown under the gate electrode pad to thereby utilize an area under the gate electrode pad as a current channel is required.

### BRIEF DESCRIPTION OF THE DRAWINGS

FIG. 1 is a schematic view illustrating a cross-section of a semiconductor device according to an embodiment;

FIGS. 2A and 2B are plan views schematically illustrating the semiconductor device according to the embodiment;

FIG. 3A to FIG. 9 are cross-sectional views schematically illustrating manufacturing processes of the semiconductor device according to the embodiment; and

FIG. 10 is a schematic view illustrating a cross-section of a semiconductor device according to a variation of the embodiment.

### DETAILED DESCRIPTION

In general, according to one embodiment, a semiconductor device includes a first main electrode, a control electrode, an extraction electrode, a second insulating film, a plurality of contact electrodes, and a control terminal. The first main electrode is electrically connected to a first semiconductor region of a first conductivity type and a second semiconductor region of a second conductivity type selectively provided on a surface of the first semiconductor region. The control electrode is provided on the first semiconductor region via a first insulating film. The extraction electrode is electrically connected to the control electrode. The second insulating film is provided on the first main electrode and the extraction electrode. The plurality of contact electrodes are provided in an inside of a plurality of first contact holes formed in the second insulating film and are electrically connected to the extraction electrode. The control terminal covers portions of the first main electrode provided on the first semiconductor region, on the second semiconductor region, and on the control electrode, respectively, and the extraction electrode, is electrically connected to the plurality of contact electrodes, and is electrically insulated from the first main electrode by the second insulating film.

Hereinafter, with reference to the drawings, embodiments of the invention will be described. In the following embodiments, similar components in the drawings are marked with like reference numerals, and a detailed description is omitted as appropriate. Different components will be suitably described. Although, in the descriptions, a first conductivity type is taken as p-type and a second conductivity type is taken as n-type, a first conductivity type may be taken as n-type and a second conductivity type may be taken as p-type.

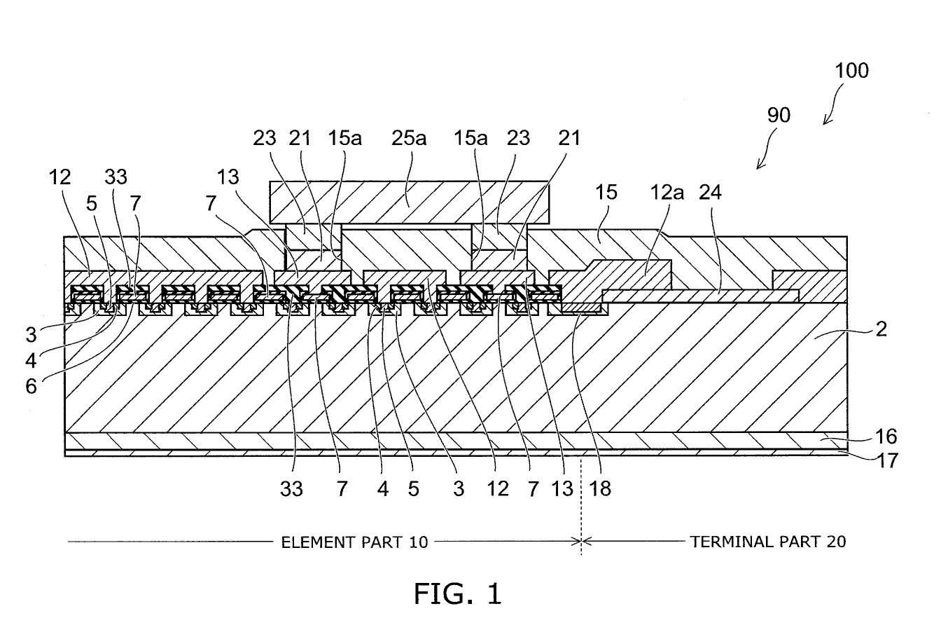

FIG. 1 is a schematic cross-sectional view illustrating a semiconductor device 100 according to the embodiment.

The semiconductor device 100 is a vertical-type planar MOSFET, for example. As illustrated in FIG. 1, in an element part 10 in which on current flows between a source electrode 12 (i.e. a first main electrode) and a drain electrode 17 (second main electrode), the device 100 includes: an n-type drift layer 2 (first semiconductor layer) provided on an n⁺ drain layer 16 (second semiconductor layer); a p-type base region 3 provided on the surface of the n-type drift layer 2; and an n-type source region 4 provided on the p-type base region 3. On the p-type base region 3, a gate electrode 7 (i.e. a control electrode) is provided via a gate insulating film 6 (i.e. a first insulating film).

The p-type base region 3 (i.e. a first semiconductor region) and the n-type source region 4 (i.e. a second semiconductor region) are electrically connected to the source electrode 12. That is, the source electrode 12 is provided while being brought into contact with the n-type source region 4 exposed between the gate electrodes 7 insulated via an interlayer insulating film 33. The source electrode 12 is also brought into contact with a p⁺ contact region 5 between the gate electrodes 7, and is electrically connected to the p-type base region 3 via the p⁺ contact region 5.

Furthermore, a gate extraction electrode 13 separated from the source electrode 12 is provided on the gate electrode 7, the n-type source region 4, and the p⁺ contact region 5. The gate extraction electrode 13 is electrically connected to the gate electrode 7 via an opening provided in the interlayer insulating film 33. In contrast, between the gate extraction electrode 13 and the n-type source region 4 and between the gate extraction electrode 13 and the p⁺ contact region 5 are insulated by the interlayer insulating film 33.

Furthermore, an insulating protective film 15 (i.e. a second insulating film) is provided while covering the source electrode 12 and the gate extraction electrode 13.

In addition, a plurality of contact holes 15a (first contact holes) communicating with the gate extraction electrode 13 is provided in the insulating protective film 15. Inside each of the contact holes 15a, a contact electrode 21 connected to the gate extraction electrode 13 is provided. Furthermore, on the contact electrode 21, a conductive adhesive layer 23 composed of an adhesive including a metal is provided to connect a connection part 25a of a gate terminal 25 to the contact electrode 21.

The connection part 25a of the gate terminal 25 is electrically connected to portions of the source electrode 12, which are provided on the p-type base region 3, n-type source region 4 and the gate electrode 7, respectively, and the contact electrodes 21 each provided in one of the plurality of contact holes 15a while covering the gate extraction electrode 13. In contrast, the gate terminal 25 and the source electrode 12 are electrically insulated each other by the insulating protective film 15.

In an end terminal part 20 provided at the periphery of the element part 10, a field oxide film 24 is provided on the surface of the n-type drift layer 2, and a field plate 12a extending on the surface of field oxide film 24 from the boundary between the element part 10 and the end terminal part 20 is further provided.

The field plate 12a functions while being combined with a girdling 18 provided in the boundary between the element part 10 and the end terminal part 20, and improves the breakdown voltage at the end terminal part 20.

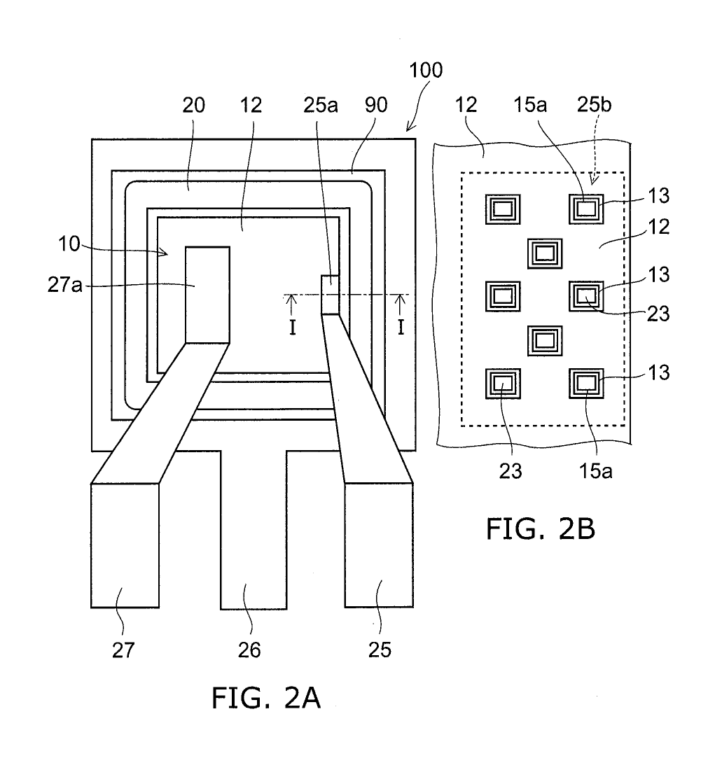

FIGS. 2A and 2B are schematic plan views illustrating the semiconductor device 100.

As illustrated in FIG. 2A, the semiconductor device 100 has a configuration in which the gate terminal 25 and a source terminal 27 (first terminal) are bonded onto the surface of a semiconductor chip 90 bonded to a drain terminal 26 (second terminal). The connection part 25a of the gate terminal 25 and a connection part 27a of the source terminal 27 have a flat-plate shape and are provided with a so-called direct lead connection, respectively. The rear surfaces of the drain terminal 26 and the semiconductor chip 90 are electrically connected each other via the drain electrode 17.

The cross-section along I-I illustrated in FIG. 2A has a cross-sectional structure illustrated in FIG. 1, and the connection part 25a of the gate terminal 25 and the semiconductor chip 90 are connected each other via the adhesive layer 23. As a material of the adhesive layer 23, a solder material can be used, for example.

In contrast, the connection part 27a of the source terminal 27 may be also connected to the surface of the semiconductor chip 90 via the adhesive layer 23 similarly. In addition, the source terminal 27 and the source electrode 12 are electrically connected to each other.

FIG. 2B is a schematic plan view illustrating a part of the semiconductor chip 90 brought into contact with the connection part 25a of the gate terminal 25. A region 25b surrounded by a dashed line illustrated in the figure is a portion which is in contact with the connection part 25a.

In the semiconductor device 100 according to the embodiment, an integrated gate electrode pad is not provided on a portion which is in contact with the gate terminal 25, instead, as illustrated in FIGS. 1 and 2B, a plurality of gate extraction electrodes 13 are provided while being separated from each other. In the configuration, the connection part 25a of the gate terminal 25 and the gate extraction electrode 13 are electrically connected to each other via the contact electrode 21 provided on the gate extraction electrode 13 and the adhesive layer 23.

In an example illustrated in FIG. 2B, eight gate extraction electrodes 13 are provided inside the region 25b, but the number of the gate extraction electrodes may be at least equal to or greater than two, and for example, the number and the size of the gate electrodes can be selected according to gate current. In FIG. 2B, although the square the adhesive layer 23 and the gate extraction electrode 13 are illustrated, the shapes of them are not restricted to be square, and they may have various shapes of such as rectangular and circular.

Further, it is not necessary for all of the eight adhesive layers 23 illustrated in FIG. 2B, for example, to be electrically connected to the gate extraction electrodes, respectively, and in order to ensure the adhesive strength of the gate terminal 25, some of them may be provided on the surface of the insulating protective film 15.

The size and the number of the gate extraction electrodes 13 can be determined to be minimum necessary values in consideration of the maximum value of the gate current. The gate current is transient current when switching of the semiconductor device is controlled, and its value is small. Accordingly, for example, the gross area of the plurality of gate extraction electrode 13 can be made smaller than the area of the source electrode 12 included in the region 25b.

In the semiconductor device 100 according to the embodiment, as illustrated in FIG. 1, a p-type base region 3, an n-type source region 4, and the gate electrode 7 are also provided in the region 25b (refer to FIG. 2B) to which the connection part 25a of the gate terminal 25 is bonded, thereby a channel is provided therein. Furthermore, since the source electrode 12 is also provided therein while being connected to the p-type base region 3 and the n-type source region 4, on current can be flown there in the similar way as the element part 10 except for the region 25b.

Accordingly, effective area of the semiconductor device 100 through which the on current flows can be enlarged, and thus, the on resistance Ron can be reduced, which allows reducing the value of Ron×S that is a product of the on resistance Ron and the area of chip S.

Furthermore, since the plurality of gate extraction electrodes 13 can be provided, the area of each of the gate extraction electrodes 13 can be made significantly smaller than that of the connection part 25a of the gate terminal 25. Thus, for example, with respect to holes generated in the n-type drift layer 2 located under the gate extraction electrode 13, discharge resistance via the p-type base region 3 and the p⁺ contact region 5 which are not directly connected to the source electrode 12 can be made small. In addition, by suppressing avalanche breakdown in the connection part 25a of the gate terminal 25, avalanche capability can be improved, or destruction by current concentration can be prevented.

In addition, as mentioned above, when the size of the gate extraction electrode 13 is reduced, it is also possible to use a configuration in which the n-type source region 4 is not included under the gate extraction electrode 13, i.e., a configuration with no channel under the gate electrode 7.

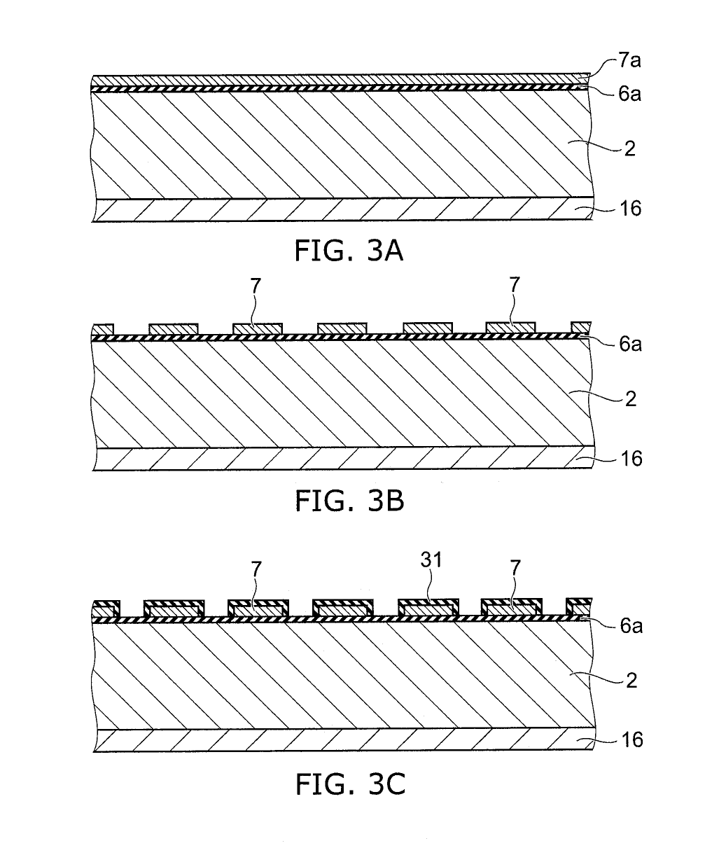

Hereinafter, with reference to FIG. 3A to FIG. 9, processes for manufacturing the semiconductor device 100 will be described.

FIG. 3A is a cross-sectional view schematically illustrating a state in which an insulating film 6a to be a gate insulating film 6 is formed on the surface of the n-type drift layer 2 and then a conductive layer 7a to be a gate electrode is formed thereon.

The n-type drift layer 2 can be formed on a silicon substrate doped with, for example, n-type impurities at a high concentration. A thermally oxidized film (SiO₂ film) can be used for the insulated film 6a, and polysilicon can be used for the conductive layer 7a.

Next, FIG. 3B illustrates a state in which the gate electrode 7 is formed from the conductive layer 7a by patterning it.

Subsequently, as illustrated in FIG. 3C, an insulating film 31 is formed on the surface of the gate electrode 7. For example, a SiO₂ film can be formed by thermally oxidizing the surface of, for example, polysilicon.

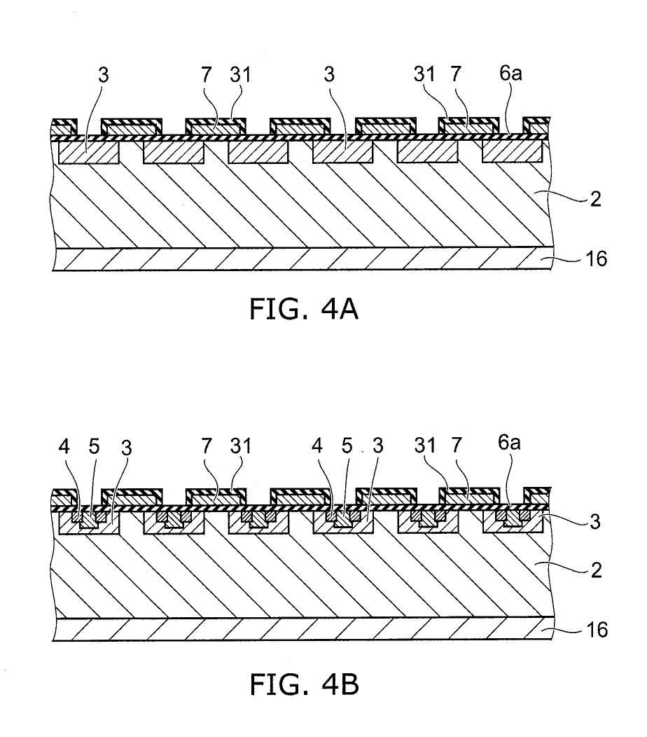

FIG. 4A is a cross-sectional view schematically illustrating a state in which the p-type base region 3 is formed on the surface of the n-type drift layer 2.

P-type impurities can be diffused on the surface of the n-type drift layer 2 by ion-implanting them thereon through the use of, for example, the gate electrode 7 as a mask, and then by subjecting the surface to a heat treatment. Boron (B) can be used as the p type impurities.

Next, as illustrated in FIG. 4B, the n-type source region 4 and the p⁺ contact region 5 are formed on the surface of the p-type base region 3.

For example, the n-type source region 4 and the p⁺ contact region 5 can be formed by selectively ion-implanting arsenic (As) (n-type impurities) and boron (B) (p-type impurities) into the surface of the p-type base region 3.

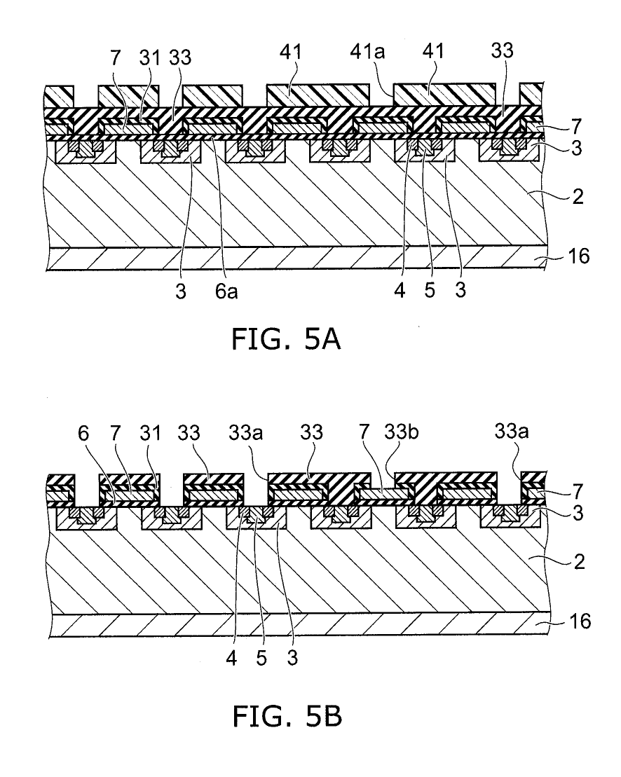

FIGS. 5A and 5B are cross-sectional views schematically illustrating a manufacturing process followed by FIG. 4B, that is, a process of forming openings for being brought into contact with the n-type source region 4 and the p⁺ contact region 5, and the gate electrode 7 in the interlayer insulating film 33.

As illustrated in FIG. 5A, a resist mask 41 with an opening 41a is formed on the interlayer insulating film 33. Subsequently, the interlayer insulating film 33 is etched by using, for example, a dry etching process.

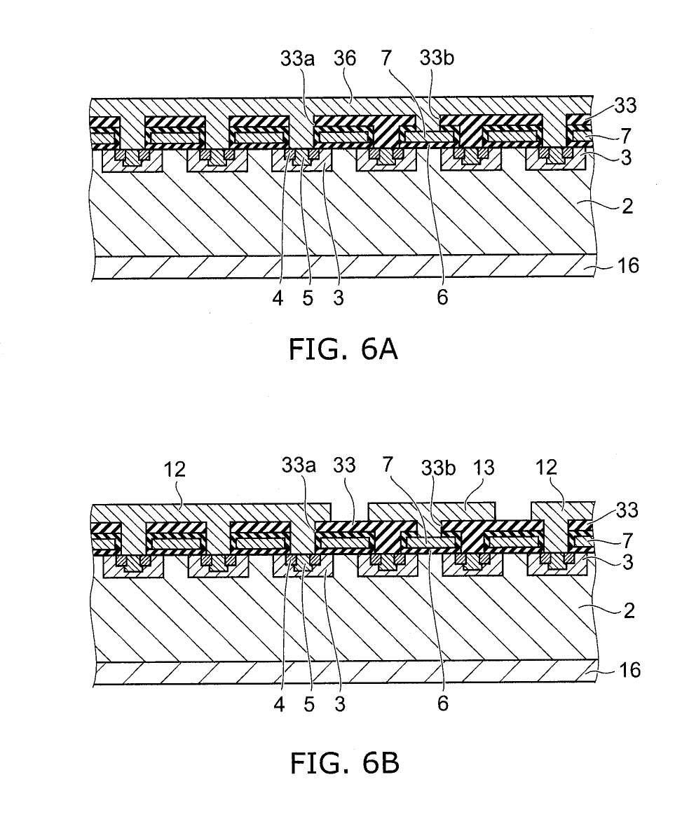

FIG. 5B illustrates a state in which openings 33a and 33b are formed in the interlayer insulating film 33, and the resist mask 41 is removed. The opening 33a is formed in order to bring the source electrode 12 into contact with the n-type source region 4 and the p⁺ contact region 5. In contrast, only the opening 33b for being in contact with the gate electrode 7 is formed in a region (refer to FIG. 6B) in which the gate extraction electrode 13 is formed, and an opening communicating with the n-type source region 4 and the p⁺ contact region 5 is not formed therein.

FIGS. 6A and 6B are cross-sectional views schematically illustrating a manufacturing process followed by FIG. 5B, that is, a process of forming the source electrode 12 and the gate extraction electrode 13.

As illustrated in FIG. 6A, an electrode metal 36 is formed on the interlayer insulating film 33 in which the openings 33a and 33b are formed. For example, an aluminum (Al) film can be formed by using a sputtering process.

Subsequently, as illustrated in FIG. 6B, the electrode metal 36 is patterned and separated into the source electrode 12 and the gate extraction electrode 13. The source electrode 12 is in contact with the n-type source region 4 and the p⁺ contact region 5 via the opening 33a. In contrast, the gate extraction electrode 13 is in contact with the gate electrode 7 via the opening 33b.

Thus, in the method for manufacturing the semiconductor device 100 according to the embodiment, the source electrode 12 and the gate extraction electrode 13 can be formed on the p-type base region 3, the n-type source region 4, and the gate electrode 7 at the same time.

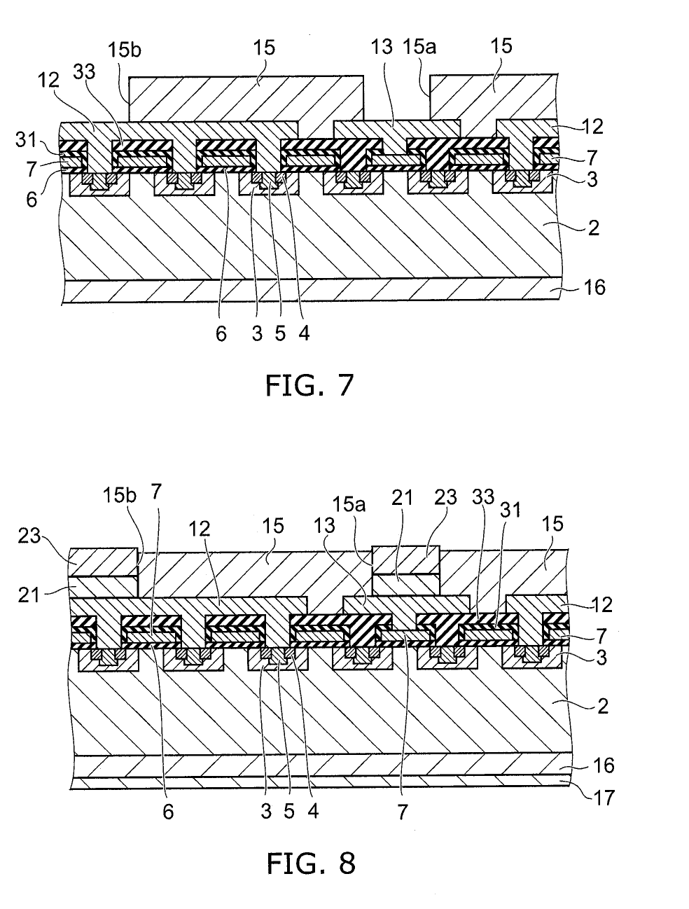

FIG. 7 illustrates a state in which the insulating protective film 15 is formed on the source electrode 12 and the gate extraction electrode 13a in a process followed by FIG. 6B.

The insulating protective film 15 protects the surface of the semiconductor chip 90 and insulates the gate terminal 25 and the source electrode 12 from each other by interposing therebetween. As the insulating protective film 15, for example, a polyimide film can be used.

A plurality of contact holes 15a are formed in the insulating protective film 15 (refer to FIG. 2B). Furthermore, a contact hole 15b (second contact hole) for electrically connecting between both of the source terminal 27 and the source electrodes 12 (refer to FIG. 7) may be formed.

Subsequently, as illustrated in FIG. 8, the contact electrode 21 and the adhesive layer 23 are formed in the inside of the contact holes 15a and 15b.

The contact electrode 21 is, for example, a nickel (Ni) electrode, and it can be formed by using a plating process.

As the adhesive layer 23, for example, a solder material for making the gate terminal 25 and the source terminal 27 adhere to each other can be used.

The contact hole 15a can be provided to have an opening size smaller than the size of the gate extraction electrode 13 so that the contact electrode 21 contacts with the inner side of the gate extraction electrode 13.

For example, when the adhesive layer 23 makes use of a solder material, the contact electrode 21 using Ni functions as a barrier layer preventing the migration of the solder. Furthermore, as illustrated in FIG. 8, by forming the contact electrode 21 so as to be in contact with the inner side of the gate extraction electrode 13, it is possible to stop the solder material entering along the interface between the contact electrode 21 and the insulating protective film 15 at the surface of the gate extraction electrode 13.

Next, as illustrated in FIGS. 2A and 2B, the semiconductor chip 90 is cut off from the substrate and bonded to the drain terminal 26. Then, the gate terminal 25 and the source terminal 27 are bonded to the surface of the semiconductor chip 90, respectively.

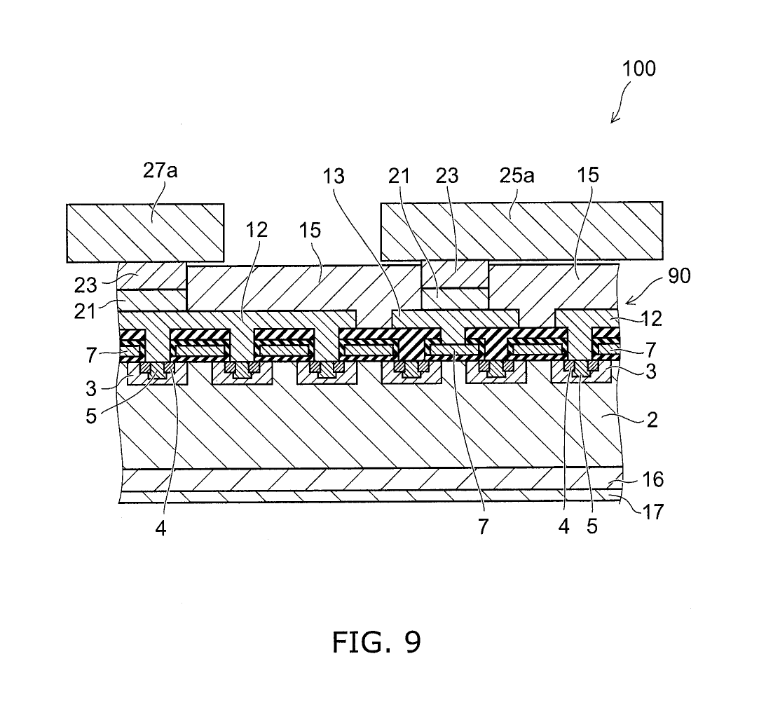

Then, as illustrated in FIG. 9, the connection part 25a of the gate terminal 25 and the connection part 27a of the source terminal 27 are connected to the gate extraction electrode 13 and the source electrode 12 via the adhesive layer 23 and the contact electrode 21, respectively.

In the semiconductor device 100 according to the embodiment, the source electrode 12 connected to the n-type source region 4 and the p⁺ contact region 5 is also provided under the connection part 25a and insulated from the connection part 25a by the insulating protective film 15.

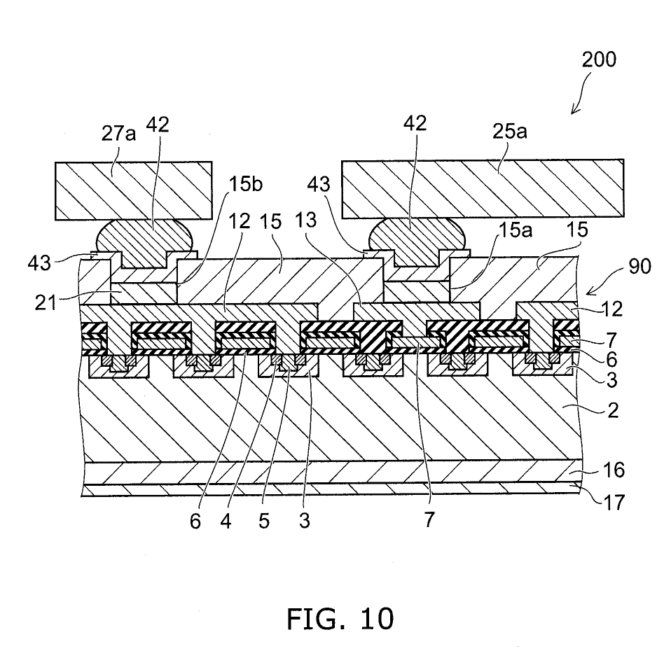

FIG. 10 is a schematic view illustrating a cross-section of a semiconductor device 200 according to a variation of the embodiment.

The semiconductor device 200 differs from the semiconductor device 100 in that the connection part 25a of the gate terminal 25 and the connection part 27a of the source terminal 27 are connected to the contact electrode 21 with a metal bump 42, respectively. As the metal bumps 42, solder balls can be used, for example.

On each of the contact electrodes 21 provided in the inside of the contact holes 15a and 15b of the insulating protective film 15, respectively, a bump electrode 43 is provided. The bump electrode 43 can be formed by using, for example, a Ni film.

At the center of the bump electrodes 43, recesses corresponding to the openings of the contact holes 15a and 15b are present, respectively, thereby, for example, the ball-shaped metal bumps 42 can be guided on the openings of the contact holes 15a and 15b, respectively.

Then, the connection part 25a of the gate terminal 25 and the connection part 27a of the source terminal 27 can be connected to the surface of the semiconductor chip 90 by thermo-compressing them from above the metal bumps 42 located on the openings of the contact holes 15a and 15.

As described the above, with reference to one embodiment according to the invention, the invention has been explained, but the invention is not limited to the embodiment. For example, embodiments of such as design change and material change that can be carried out by those skilled in the art based on the technical level at the time of application of the invention, which have the same technical idea as the invention, are also included in the technical scope of the invention.

For example, in the semiconductor devices 100 and 200 according to the embodiment, so-called vertical planar gate power MOSFETs are exemplified, they may be a MOSFET with a trench gate structure or other switching devices such as an IGBT. Furthermore, the invention can be applied to a device with a lateral structure. Moreover, the invention can be applied to a device using a material other than silicon, such as GaN or SiC.

In the embodiment, configurations, in which the gate terminal 25 is electrically connected to the gate electrode 7, are described as examples, but even if the gate terminal 25 is connected to another part, the invention can be applied for utilizing a region through which on current does not flow as an effective region.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device comprising:
a first main electrode electrically connected to a first semiconductor region of a first conductivity type and a second semiconductor region of a second conductivity type selectively provided on a surface of the first semiconductor region;
a control electrode provided on the first semiconductor region via a first insulating film;
an extraction electrode electrically connected to the control electrode;
a second insulating film provided on the first main electrode and the extraction electrode;
a plurality of contact electrodes provided in an inside of a plurality of first contact holes formed in the second insulating film and electrically connected to the extraction electrode; and
a control terminal covering portions of the first main electrode provided on the first semiconductor region, on the second semiconductor region, and on the control electrode, respectively, and the extraction electrode, electrically connected to the plurality of contact electrodes, and electrically insulated from the first main electrode by the second insulating film.

2. The device according to claim 1, further comprising
a third insulating film covering the first semiconductor region and the second semiconductor region,
the extraction electrode being insulated from the first semiconductor region and the second semiconductor region by the third insulating film.

3. The device according to claim 1, further comprising
a connection material including a metal provided between the contact electrode and the control terminal.

4. The device according to claim 3, wherein the connection material is provided between the second insulating film and the control terminal.

5. The device according to claim 3, wherein the connection material is a solder material or a metal bump.

6. The device according to claim 5, wherein a recess for guiding the metal bump is provided on an upper portion of the contact electrode.

7. The device according to claim 1, wherein a plurality of the extraction electrodes are provided apart from each other, and a plurality of the contact electrodes are provided in an inside of corresponding one of a plurality of the first contact holes, respectively.

8. The device according to claim 1, wherein a gross area of the extraction electrode is smaller than an area of a part of the first main electrode covered with the control terminal.

9. The device according to claim 1, wherein the first semiconductor region provided directly under the extraction electrode does not include the second semiconductor region.

10. The device according to claim 1, wherein the first main electrode and the extraction electrode include aluminum.

11. The device according to claim 1, wherein the second insulating film is a polyimide film.

12. The device according to claim 1, wherein the contact electrode includes nickel.

13. The device according to claim 1, wherein an opening of the first contact hole is provided on an inner side than an outer edge of the extraction electrode.

14. The device according to claim 1, further comprising:
a second main electrode electrically connected to a rear surface of a first semiconductor layer of the second conductivity type provided with the first semiconductor region via a second semiconductor layer of the second conductivity type;
a first terminal electrically connected to the first main electrode; and
a second terminal electrically connected to the second main electrode.

15. The device according to claim 14, wherein a connection part of the control terminal and a connection part of the first terminal are provided in a flat-plate shape.

16. The device according to claim 14, wherein the first terminal is electrically connected to the first main electrode via the contact electrode provided in an inside of a second contact hole formed in the second insulating film.

17. The device according to claim 14, further comprising:
a connection material including a metal provided between the contact electrode and the first terminal.

18. The device according to claim 14, wherein a rear surface of a semiconductor chip including the first semiconductor layer and the second semiconductor layer is bonded to the second terminal via the second main electrode.

19. A method for manufacturing a semiconductor device, the semiconductor device including: a main electrode electrically connected to a first semiconductor region of a first conductivity type and a second semiconductor region of a second conductivity type selectively provided on a surface of the first semiconductor region; a control electrode provided on the first semiconductor region via a first insulating film; an extraction electrode electrically connected to the control electrode; a second insulating film provided on the main electrode and the extraction electrode; and in a region where a part of the main electrode and the extraction electrode are covered and a control terminal is bonded, a plurality of contact electrodes provided in an inside of a plurality of contact holes formed in the second insulating film and electrically connecting the control terminal and the extraction electrode, the method comprising:
forming the main electrode and a metal film to be the extraction electrode simultaneously on the first semiconductor region, the second semiconductor region, and the control electrode.

20. The method according to claim 19, wherein the metal film includes aluminum.
